(19) United States
(12) Patent Application Publication
(10) Pub. No.: US 2013/0149078 A1
(43) Pub. Date: Jun. 13, 2013

(54) SUBSTRATE-PROCESSING APPARATUS AND SUBSTRATE-TRANSFERRING METHOD

(71) Applicants: Sung Tae Je, Gyeonggi-do (KR); Il Kwang Yang, Gyeonggi-do (KR); Jun Jin Hyon, Gyeonggi-do (KR)

(72) Inventors: Sung Tae Je, Gyeonggi-do (KR); Il Kwang Yang, Gyeonggi-do (KR); Jun Jin Hyon, Gyeonggi-do (KR)

(73) Assignee: EUGENE TECHNOLOGY CO., LTD., Gyeonggi-do (KR)

(21) Appl. No.: 13/813,985

(22) PCT Filed: Aug. 30, 2011
(86) PCT No.: PCT/KR2011/006392

§ 371 Date: Feb. 4, 2013

(30) Foreign Application Priority Data
Sep. 15, 2010 (KR) 10-2010-0090613

(51) Int. Cl. H01L 21/677

(52) U.S. Cl. CPC H01L 21/677
USPC 414/222.01; 414/806

(57) ABSTRACT

According to one embodiment of the present invention, a substrate-processing apparatus includes: first and second chambers parallel to each other; a plurality of first lift pins disposed in the first chamber, and supporting a first substrate transferred to the first chamber; a plurality of second lift pins disposed in the second chamber, and supporting a second substrate transferred into the second chamber; and a transfer robot transferring the first and second substrates into the first and second chambers. The transfer robot includes first and second blades that simultaneously elevate to transfer the first and second substrates to the upper sides of the first and second lift pins, respectively. The first and second blades can move to: a moving position higher than the upper ends of the first and second lift pins; a first loading position in which the first blade is lower than the upper ends of the first lift pins and the second blade is higher than the upper ends of the second lift pins; and a second loading position in which the first and second blades are lower than the upper ends of the first and second lift pins.

### TECHNICAL FIELD

The present invention relates to a substrate-processing apparatus and a substrate-transferring method, and more particularly, to a substrate-processing apparatus which is capable of respectively transferring first and second substrates into first and second chambers and a substrate-transferring method.

### BACKGROUND ART

Various processing chambers are used to perform various processes in semiconductor manufacturing fields. These processes include, for example, cleaning, deposition, etching, and oxidation processes. The above-described processes are performed on wafers in a state where the wafers are loaded within a process chamber. The processed wafers are unloaded from the inside of the process chamber and then are moved into a process chamber which a next process is performed.

Wafers are loaded into or unloaded from a process chamber through a transfer robot. The transfer robot includes a blade (or end effector) on which the wafers are placed. The blade elevates or moves through a transfer arm connected to a rear end thereof to load the wafers into the process chamber or unload the wafers from the process chamber.

Such a wafer moves above a support member installed within the process chamber by the blade. The blade puts the wafer on upper ends of lift pins that are installed on the support member. The lift pins support the wafer in a state where the lift pins contact a back surface of the wafer. The wafer is seated on a top surface of the support member by the ascendant of the supporting member or the descendant of the lift pins. Thereafter, the processes with respect to the wafer are performed.

When the wafer is seated on the top surface of the support member, if the wafer is seated out of accurate position, it is difficult to expect that accurate processes (e.g., having the same uniformity) with respect to the wafer are performed. Thus, before the wafer is placed on the upper ends of the lift pins, the blade moves in left and right directions so that the wafer is placed in position. When the wafer is disposed at accurate coordinates, the wafer is put down on the upper ends of the lift pins.

### DISCLOSURE OF THE INVENTION

### Technical Problem

An object of the present invention is to provide a substrate-processing apparatus capable of respectively loading substrates into a plurality of chambers and a substrate-transferring method.

Another object of the present invention is to provide a substrate-processing apparatus capable of reducing a time taken for transferring substrates a substrate-transferring method.

Further another object of the present invention will become evident with reference to following detailed descriptions and accompanying drawings.

### Technical Solution

According to an aspect of the present invention, there is provided an apparatus for processing a substrate, the apparatus including: first and second chambers disposed parallel to each other; first and second lift pins disposed within the first and second chambers to support the first and second substrates transferred into the first and second chambers, respectively; and a transfer robot transferring the first and second substrates into the first and second chambers, wherein the transfer robot includes first and second blades which are elevated at the same time to transfer the first and second substrates on top surfaces of the first and second lift pins, wherein the first and second blades are moved into a moving position in which the first and second blades are disposed higher than upper ends of the first and second lift pins, a first loading position in which the first blade is disposed lower than the top surfaces of the first lift pins, and the second blade is disposed higher than upper ends of the second lift pins, and a second loading position in which the first and second blades are disposed lower than the upper ends of the first and second lift pins.

The upper ends of the first lift pins may be disposed higher than those of the second lift pins, and the first and second blades may be disposed at substantially the same height.

The upper ends of the first lift pins are disposed at substantially the same height as those of the second lift pins, and the first blade is disposed lower than second blade.

The apparatus of any one of according to another aspect of the present invention, further including first and second support members supporting the first and second substrates respectively placed on the top surfaces of the first and second lift pins at an ascending position, the first and second support members having first and second through holes through which the first and second lift pins pass at a descending position, wherein the first and second lift pins are fixedly disposed on bottom walls of the first and second chambers, respectively.

The transfer robot may align the first substrate placed on the first blade at the moving position and aligns the second substrate at the first loading position.

The first and second blades may descend to successively moved to the moving position and the first and second loading position.

According to another aspect of the present invention, there is provided a substrate-transferring method for transferring first and second substrates onto top surfaces of first and second lift pins installed respectively within a first and second chamber disposed parallel to each other, the substrate-transferring method including: simultaneously moving first and second blades on which the first and second substrates are disposed from a moving position that is higher than upper ends of the first and second lift pins toward upper sides of the first and second lift pins; aligning the first substrate disposed on the first blade; moving the first and second blades downward to a first loading position at which the first blade is disposed lower than the upper ends the first lift pins, and the second blade is higher than the upper ends of the second lift pins; aligning the second substrate disposed on the second blade; and moving the first and second blades downward to a second loading position at which the first and second blades are disposed lower than the upper ends of the first and second lift pins.

The upper ends of the first lift pins are higher than the upper ends of the second lift pins, and the first and second blades are disposed at substantially the same height.

The upper ends of the first lift pin may be disposed at substantially the same height as the upper ends of the second lift pin, and the first blade may be disposed lower than the second blade.

The substrate-transferring method of according to another aspect of the present invention, further including moving first and second support members having first and second through holes through which the first and second lift pins pass from a descending position to an ascending position to support the first and second substrates respectively disposed on the top surfaces of the first and second lift pins by using the first and second support members.

### Advantageous Effects

An object of the present invention is to provide a substrate-processing apparatus capable of respectively loading substrates into a plurality of chambers and a substrate-transferring method.

Another object of the present invention is to provide a substrate-processing apparatus capable of reducing a time taken for transferring substrates a substrate-transferring method.

### BRIEF DESCRIPTION OF THE DRAWINGS

FIG. 1 is a schematic view of a substrate-processing apparatus according to an embodiment of the present invention.

FIG. 2 is a schematic view a transfer robot transferring a substrate into a chamber of FIG. 1.

FIGS. 3 to 6 are schematic views of a substrate-transferring method according to an embodiment of the present invention.

FIG. 7 is a schematic view of a transfer robot according to another embodiment of the present invention.

FIGS. 8 to 10 are schematic views of a substrate-transferring method according to another embodiment of the present invention.

### BEST MODE

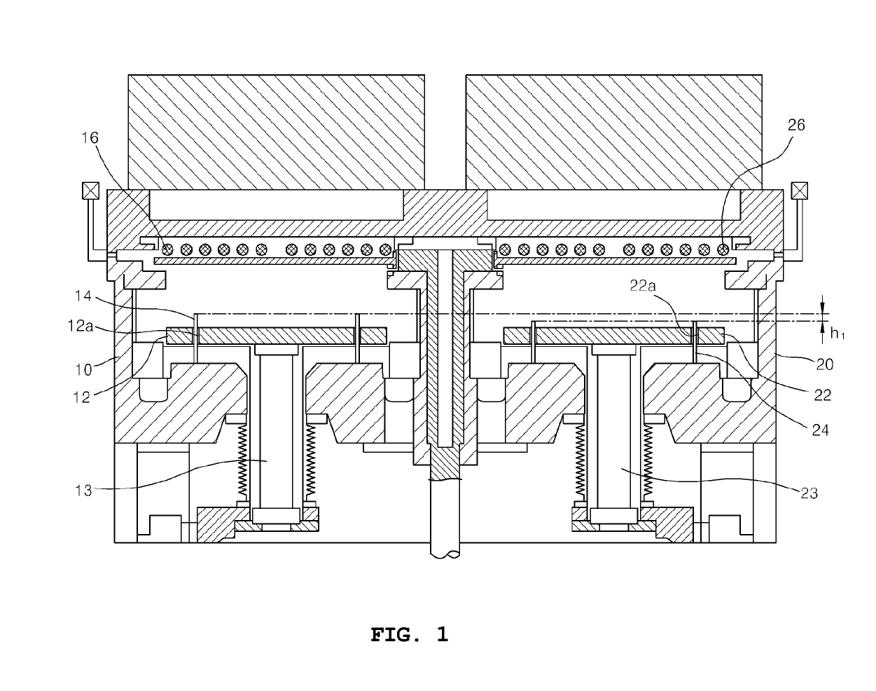

Hereinafter, exemplary embodiments of the present invention will be described in detail with reference to FIGS. 1 to 10. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the shapes of components are exaggerated for clarity of illustration.

FIG. 1 is a schematic view of a substrate-processing apparatus according to an embodiment of the present invention. As shown in FIG. 1, the substrate-processing apparatus includes first and second chambers 10 and 20. The first and second chambers 10 and 20 are parallely disposed adjacent to each other. The same process may be performed within the first and second chambers 10 and 20. Alternatively, different processes (e.g., a series of processes successively performed within the first and second chambers 10 and 20) may be performed within the first and second chamber 10 and 20.

As shown in FIG. 1, first and second support members 12 and 22 are installed within the first and second chambers 10 and 20, respectively. The first and second support members 12 and 22 may be elevated by lift shafts 13 and 23 connected to lower ends thereof. That is, the first and second support member 12 and 22 may ascend or descend to be converted into a descending position as shown in FIG. 1 and an ascending position which is moved upward from the descending position.

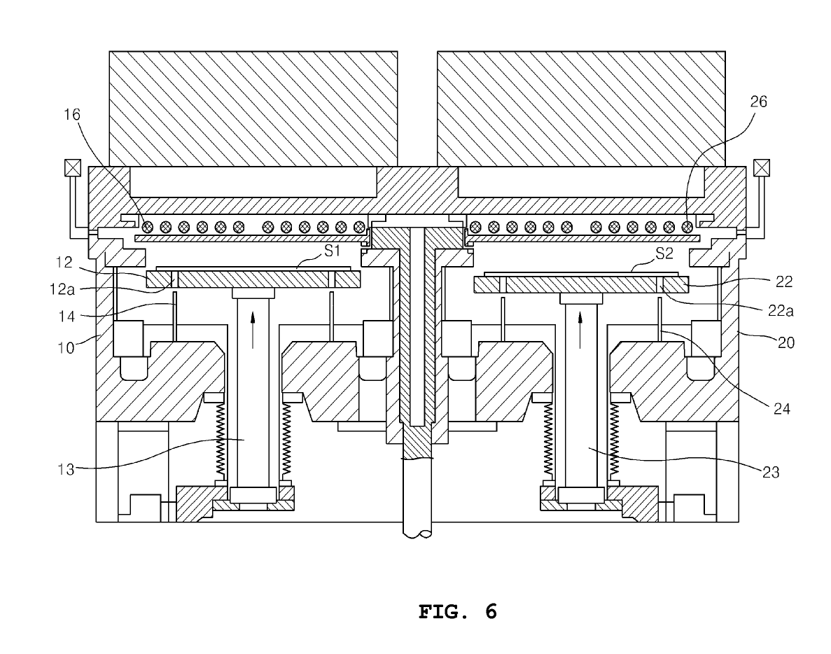

The first and second support members 12 and 22 have a plurality of first and second through holes 12a and 22a vertically passing therethrough, respectively. When the first and second support members 12 and 22 are disposed at the descending position, first and second lift pins 14 and 24 to be described later protrude upward from the first and second support members through the first and second through holes 12a and 22a. As described below (see FIG. 6), when the first and second support members 12 and 22 are disposed at the ascending position, the first and second lift pins 14 and 24 are disposed within the first and second through holes 12a and 22a or disposed under the first and second support members 12 and 22 according to lengths thereof.

The first and second lift pins 14 and 24 initially support substrates transferred within the first and second chambers 10 and 20, respectively. The first and second lift pins 14 and 24 are maintained to stand up in a state where lower ends of the first and second lift pins 14 and 24 are respectively fixed to bottom walls of the first and second chambers 10 and 20. As described above, when the first and second support members 12 and 22 are disposed at the descending position, the first and second lift pins 14 and 24 protrude upward from the first and second support members through the first and second through holes 12a and 22a. Here, the first and second lift pins 14 and 24 initially support substrates transferred into the first and second chambers 10 and 20, respectively.

Here, as shown in FIG. 1, the upper ends of the first and second lift pins 14 and 24 have a height difference h1 therebetween. That is, when substrates are respectively transferred into the first and second chambers 10 and 20, the substrate transferred into the first chamber 10 is disposed higher than the substrate transferred into the second chamber 20.

First and second antennas 16 and 26 are installed above the first and second support members 12 and 22. The first and second antennas 16 and 26 generate electric fields within the first and second chambers 10 and 20, respectively, by a power source applied from the outside. When a reaction gas is supplied into the first and second chambers 10 and 20, plasma is generated due to the electric fields.

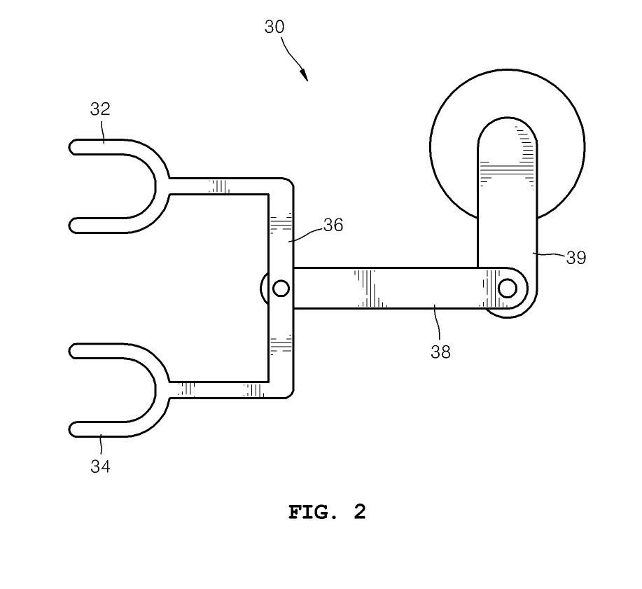

FIG. 2 is a schematic view a transfer robot transferring a substrate into the chamber of FIG. 1. A transfer robot 30 includes first and second blades 32 and 34, a connection arm 36 connecting the first and second blades to each other, and a plurality of extension arms 38 and 39 connected to the connection arm 36. The first and second blades 32 and 34 are disposed at substantially the same height. In a state where the first and second blades 32 and 34 are connected to the connection arm 36, the first and second blades 23 and 34 may be elevated or moved by an operation (or an operation of a driving part connected to the extension arms 38 and 39) of the extension arms 38 and 39. As described above, the substrates are placed on the first and second blades 32 and 34. The first and second blades 32 and 34 are moved into the first and second chambers 10 and 20 through gate valves (not shown) disposed in side walls of the first and second chambers 10 and 20 to load the substrates into the first and second chambers 10 and 20, respectively.

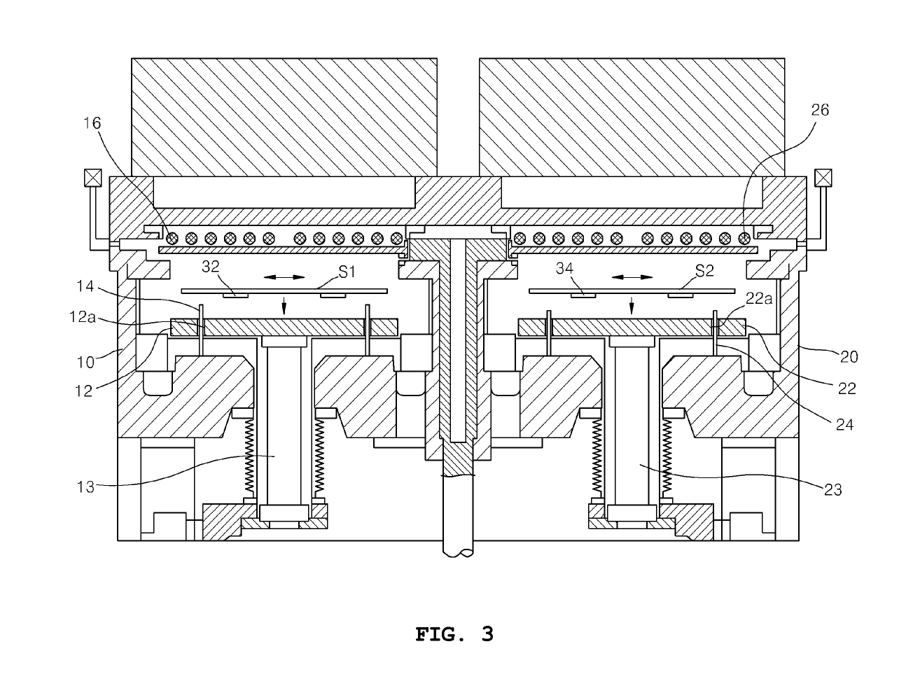

FIGS. 3 to 6 are schematic views of a substrate-transferring method according to an embodiment of the present invention. Hereinafter, a substrate-transferring method will be described with reference to FIGS. 3 to 6.

As shown in FIG. 3, first and second substrates S1 and S2 are placed on top surfaces of the first and second blades 32 and 34, respectively. As described above, the first and second substrates S1 and S2 are moved into the first and second chambers 10 and 20 through gate valves (not shown) disposed in side walls of the first and second chambers 10 and 20, respectively. Here, the first and second blades 32 and 34 are moved together with the connection arm 36 at the same time. The first and second blades 23 and 34 are moved above the support member 12 and 22. Here, the top surfaces (or bottom surfaces of the first and second substrates S1 and S2) of the first and second blades 32 and 34 are disposed higher than upper ends of first and second lift pins 14 and 24 (hereinafter, referred to as a “moving position”).

Thereafter, as shown in FIG. 3, the first substrate S1 is moved horizontally and then aligned in position with the first support member 12. That is, a connection arm 36 is moved horizontally to move the first substrate S1 horizontally. Here, the first and second blades 32 and 34 are moved together with the connection arm 36, and also the second substrate S2 disposed on the second blade 34 is moved together. However, it is determined whether the first substrate S1 is aligned while ignoring the alignment of the second substrate S2. When the alignment of the first substrate S1 is completed, the connection arm 36 descends to put the first substrate S1 down on upper ends of the first lift pins 14.

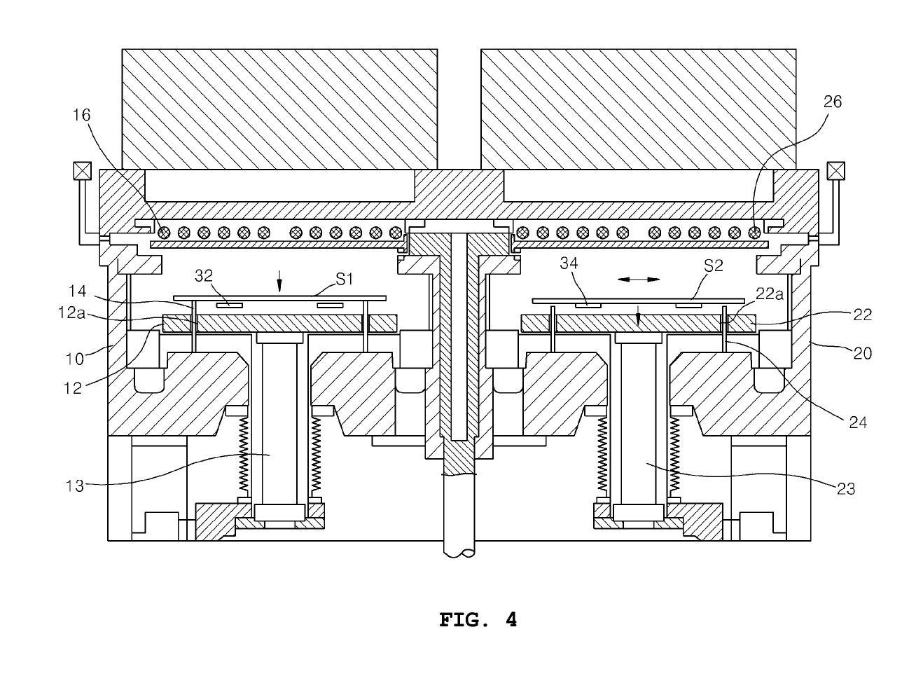

As shown in FIG. 4, in a state where the top surface (or a bottom surface of the first substrate S1) of the first blade 32 is disposed at a position greater the upper ends of the first lift pins 14, and the top surface (or a bottom surface of the second substrate S2) of the second blade 34 is disposed higher the upper ends of the second lift pins 24 (hereinafter, referred to as a “first loading position”), the first substrate S1 is placed on the upper ends of the first lift pins 14, and the second substrate S2 is placed on the top surface of the second blade 34.

In this state, through the same method as that of the first substrate, the second substrate S2 is moved horizontally and then aligned in position with the second support member 22. That is, the connection arm 36 is moved horizontally to move the second substrate S2 horizontally. Here, the first and second blades 32 and 34 are moved together with the connection arm 36. However, since the first substrate S1 is separated from the top surface of the first blade 32 and placed on the first lift pins 14, the moving of the first blade 32 doesn't affect a position of the first substrate. Thus, the first substrate S1 may be maintained in the aligned state through the above-described process. Thereafter, it is determined whether the second substrate S2 is aligned. When the alignment of the second substrate S2 is completed, the connection arm 36 descends to put the second substrate S2 down on the upper ends of the second lift pins 24.

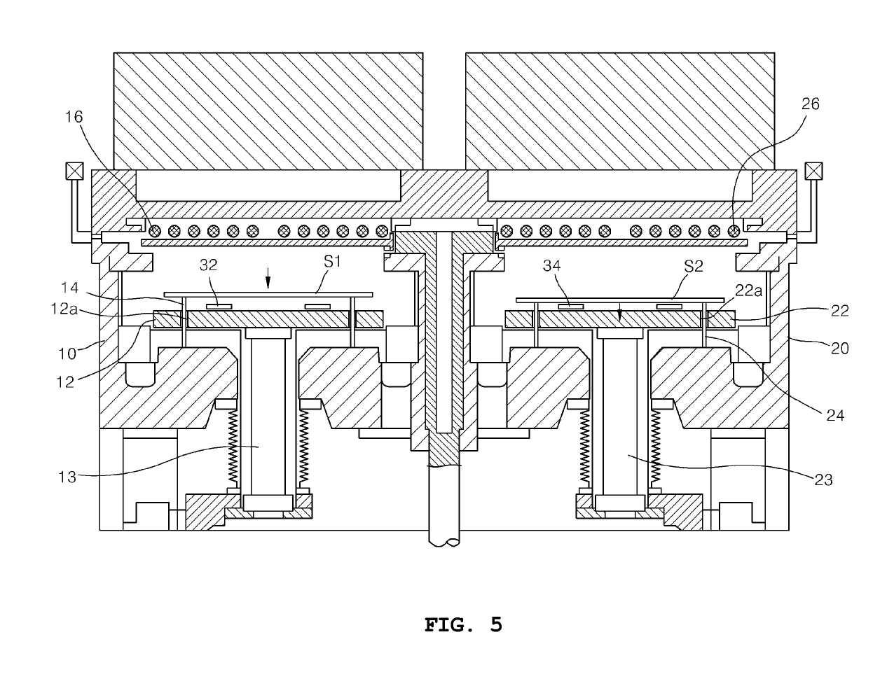

As shown in FIG. 5, in a state where the top surfaces (or the bottom surfaces of the first and second substrates S1 and S2) of the first and second blades 32 and 34 are disposed lower than the upper ends of the first and second lift pins 14 and 24 (hereinafter, referred to as a “second loading position”), the first and second substrate S1, S2 are placed on the upper ends of the first and second lift pins 14 and 24, respectively. Thereafter, the first and second blades 32 and 34 are moved backward and separated from upper portions of the first and second support members 12 and 22. Then, the first and second blades 32 and 34 get out of the first and second chambers 10 and 20 through the above-described gate valves (not shown).

Thereafter, as shown in FIG. 6, the first and second support member 12 and 22 ascend to seat the first and second substrate S1 and S2, which are respectively disposed on the first and second lift pins 14 and 24, on top surfaces of the first and second support member 12 and 22. Here, since the first and second substrate S1 and S2 are completely aligned through the above-described method, the first and second substrates S1 and S2 may be disposed in position.

As described above, when the substrates are respectively loaded into the plurality of the chambers, a time taken for loading the substrates may be reduced. That is, a plurality of substrates may be introduced into chambers through the same operation. Also, the plurality of substrates may be placed on the lift pins through the same descent process. That is, since the plurality of substrates share most of processes except for the alignment process, the number of operations for loading the substrates may be reduced. Thus, the loading and the alignment may be completed within a short time.

Although two chambers are exemplified in the current embodiment, the contents of the current embodiment may be applied to at least three chambers. For example, the contents of the current embodiment may be realized as it is by using height differences among the lift pins disposed in each of the at least three.

Also, although the method of transferring the substrates into each of the plurality of chambers parallely disposed adjacent to each other is described in the current embodiment, the present invention is not limited thereto. For example, the plurality of chambers may be spaced apart from each other or vertically disposed. Here, the forgoing embodiment may also be applied into the above-described arrangement. Also, although the lift pins are fixedly installed on the bottom wall of the chamber, the present invention is not limited thereto. For example, the lift pins may be fixed to the support member and elevated through the through holes of the support member.

Although the present invention is described in detail with reference to the exemplary embodiments, the invention may be embodied in many different forms. Thus, technical idea and scope of claims set forth below are not limited to the preferred embodiments.

### MODE FOR CARRYING OUT THE INVENTION

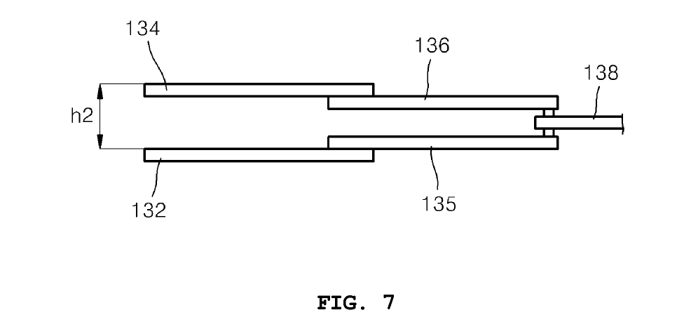

FIG. 7 is a schematic view of a transfer robot according to another embodiment of the present invention. As shown in FIG. 7, a transfer robot includes first and second blades 132 and 134. A top surface of the second blade 134 is disposed higher than that of the first blade 132 (height different=h2). The first and second blades 132 and 134 are connected to the extension arms 138 through the first and second extension arms 135 and 136, respectively. When the extension arm 138 is operated, the first and second blades 132 and 134 are operated together with each other. An operation of the transfer robot is the same as the above-described embodiment on the whole.

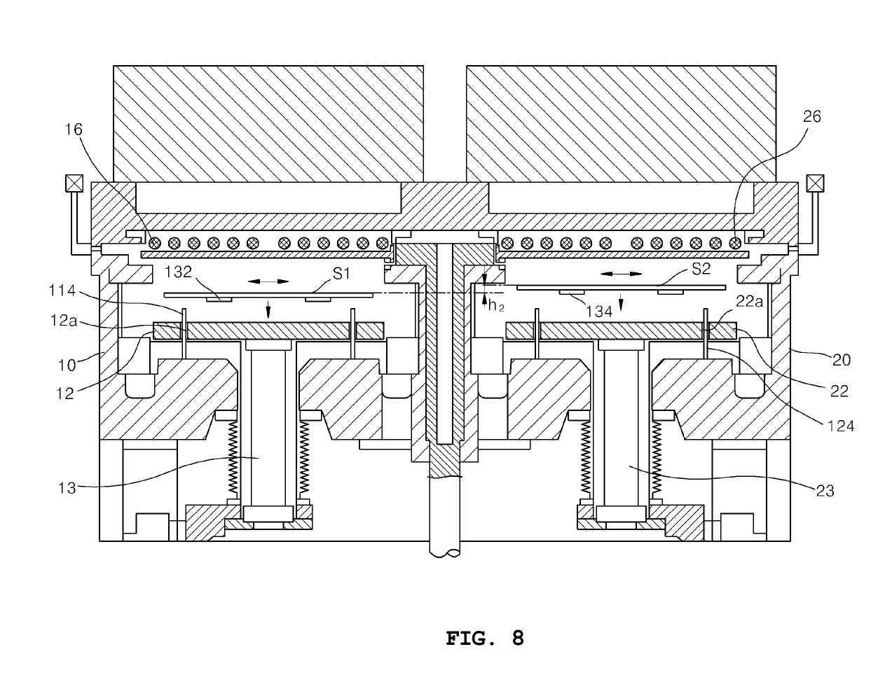

FIGS. 8 to 10 are schematic views of a substrate-transferring method according to another embodiment of the present invention. Hereinafter, a substrate-transferring method will be described with reference to FIGS. 8 to 10.

As shown in FIG. 8, first and second substrates S1 and S2 are disposed on top surfaces of first and second blades 132 and 134, respectively. The first and second blades 132 and 134 are simultaneously moved to upper sides of a first and second support member 12 and 22 by an operation of an extension arm 138, respectively. Here, upper ends of first and second lift pins 114 and 124 are disposed at substantially the same height. The top surface of the second blade 134 is disposed higher than that of the first blade 132 (height different=h2). Also, the top surface (or bottom surfaces of the first and second substrates S1 and S2) of the first and second blades 132 and 134 are disposed higher than the upper ends of the first and second lift pins 114 and 124 (hereinafter, referred to as a “moving position”).

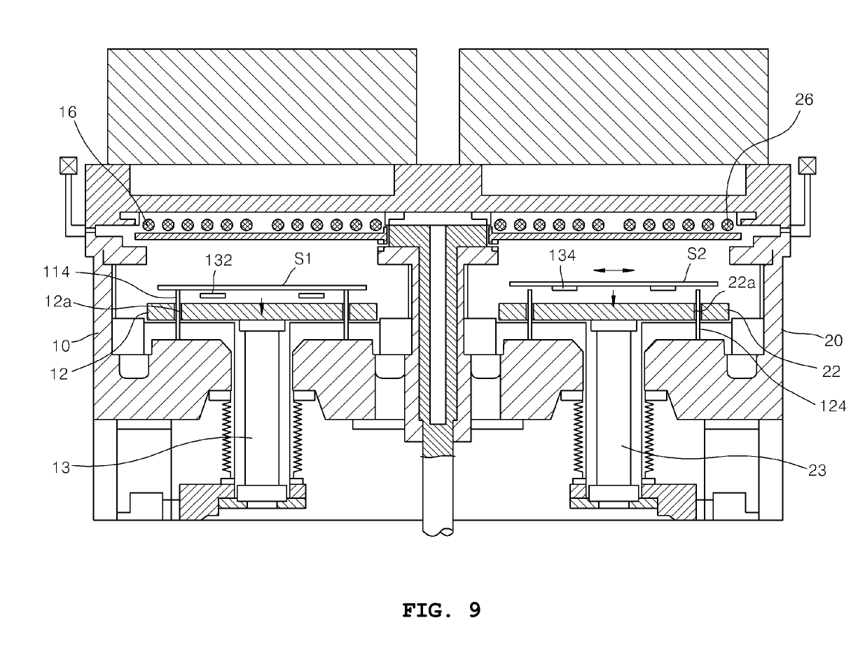

Thereafter, as shown in FIG. 9, the first substrate S1 is aligned in position on the first support member 12 by moving the first substrate S1 in left and right directions. That is, the extension arm 138 is horizontally moved to horizontally move the first substrate S1. Here, the first and second blades 132 and 134 are moved together with the extension arms 138 and also moved together with the second substrate S2 placed on the second blade 134. However, it is determined whether the first substrate S1 is aligned while ignoring the alignment of the second substrate S2. The alignment of the first substrate S1 is completed, the extension arm 138 descends to put the first substrate S1 down on the upper ends of the first lift pins 114.

As shown in FIG. 9, in a state where the top surface of the first blade 132 (or the bottom surface of the first substrate S1) is disposed at a position lower than the upper ends of the first lift pins 114, and also the top surface of the second blade 134 (or the bottom surface of the second substrate S2) is disposed higher than the upper ends of the second lift pins 124 (hereinafter, referred to as a “first loading position”), the first substrate S1 is placed on the upper ends of the first lift pins 114, and the second substrate S2 is placed on the top surface of the second blade 134.

In this state, the second substrate S2 is aligned in position on the second support member 22 by moving the second substrate S2 in left and right directions through the same process as that of the first substrate S1. That is, the extension arm 138 is horizontally moved to horizontally move the second substrate S2. Here, the first and second blades 132 and 134 are moved together with the extension arms 138. However, since the first substrate S1 is separated from the top surface of the first blade 132 and thus placed on the first lift pins 114, the movement of the first blade 132 doesn't affect a position of the first substrate S1. Thus, the first substrate S1 may be maintained in the aligned state through the previous processes. Thereafter, it is determined whether the second substrate S2 is aligned. When the alignment of the second substrate S2 is completed, the extension arm 138 descends to put the second substrate S2 down on the upper ends of the second lift pins 124.

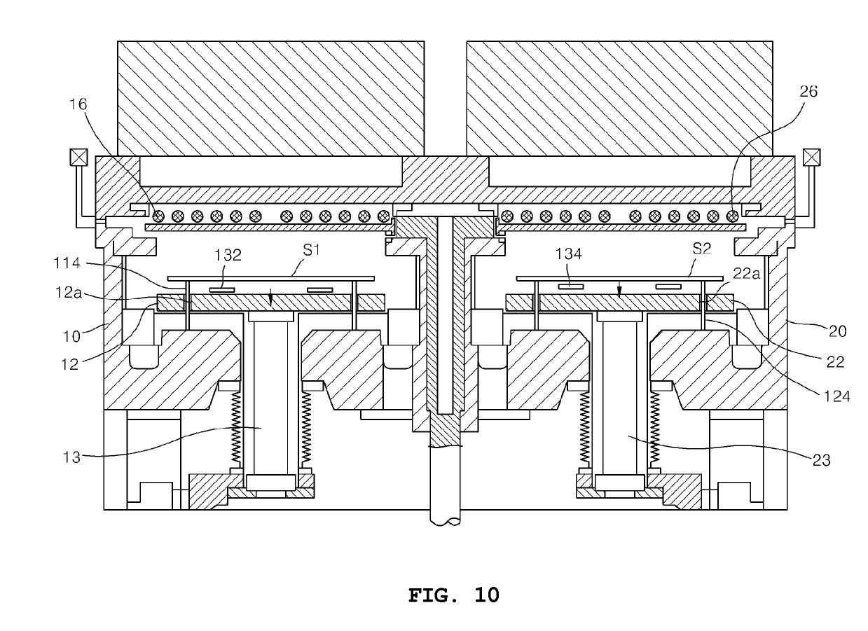

As shown in FIG. 10, in a state where the top surface of the first and second blade 132 and 134 (or the bottom surface of the first and second substrate) is disposed at a position lower than the upper ends of the first and second lift pins 114 and 124 (hereinafter, referred to as a “second loading position”), the first and second substrate S1 and S2 are respectively disposed on the top ends of the first and second lift pins 114 and 124. Thereafter, the first and second blades 132 and 134 are retreated and removed from the top surface of the first and second support members 12 and 22. The first and second blades 132 and 134 get out from the first and second chambers 10 and 20 through the above-described the gate valve (not shown).

### INDUSTRIAL APPLICABILITY

The present invention may be applicable to various substrates processing apparatuses and methods.

1. An apparatus for processing a substrate, the apparatus comprising:
first and second chambers disposed parallel to each other;
first and second lift pins disposed within the first and second chambers to support the first and second substrates transferred into the first and second chambers, respectively; and
a transfer robot transferring the first and second substrates into the first and second chambers,
wherein the transfer robot comprises first and second blades which are elevated at the same time to transfer the first and second substrates on top surfaces of the first and second lift pins,
wherein the first and second blades are moved into a moving position in which the first and second blades are disposed higher than upper ends of the first and second lift pins, a first loading position in which the first blade is disposed lower than the top surfaces of the first lift pins, and the second blade is disposed higher than upper ends of the second lift pins, and a second loading position in which the first and second blades are disposed lower than the upper ends of the first and second lift pins.

2. The apparatus of claim 1, wherein the upper ends of the first lift pins are disposed higher than those of the second lift pins, and
the first and second blades are disposed at substantially the same height.

3. The apparatus of claim 1, wherein the upper ends of the first lift pins are disposed at substantially the same height as those of the second lift pins, and
the first blade is disposed lower than second blade.

4. The apparatus of claim 1, further comprising first and second support members supporting the first and second substrates respectively placed on the top surfaces of the first and second lift pins at an ascending position, the first and second support members having first and second through holes through which the first and second lift pins pass at a descending position,
wherein the first and second lift pins are fixedly disposed on bottom walls of the first and second chambers, respectively.

5. The apparatus of claim 1, wherein the transfer robot aligns the first substrate placed on the first blade at the moving position and aligns the second substrate at the first loading position.

6. The apparatus of claim 1, wherein the first and second blades descend to successively moved to the moving position and the first and second loading position.

7. A substrate-transferring method for transferring first and second substrates onto top surfaces of first and second lift pins installed respectively within a first and second chamber disposed parallel to each other, the substrate-transferring method comprising:
simultaneously moving first and second blades on which the first and second substrates are disposed from a moving position that is higher than upper ends of the first and second lift pins toward upper sides of the first and second lift pins;
aligning the first substrate disposed on the first blade;
moving the first and second blades downward to a first loading position at which the first blade is disposed lower than the upper ends the first lift pins, and the second blade is higher than the upper ends of the second lift pins;
aligning the second substrate disposed on the second blade; and
moving the first and second blades downward to a second loading position at which the first and second blades are disposed lower than the upper ends of the first and second lift pins.

8. The substrate-transferring method of claim 7, wherein the upper ends of the first lift pins are higher than the upper ends of the second lift pins, and
the first and second blades are disposed at substantially the same height.

9. The substrate-transferring method of claim 7, wherein the upper ends of the first lift pin is disposed at substantially the same height as the upper ends of the second lift pin, and
the first blade is disposed lower than the second blade.

10. The substrate-transferring method of claim 7, further comprising moving first and second support members having first and second through holes through which the first and second lift pins pass from a descending position to an ascending position to support the first and second substrates respectively disposed on the top surfaces of the first and second lift pins by using the first and second support members.
